(19) United States
(12) Patent Application Publication
(10) Pub. No.: US 2020/0174073 A1
(43) Pub. Date: Jun. 4, 2020

(54) DEVICE INSPECTION METHOD

(71) Applicant: TOKYO ELECTRON LIMITED, Tokyo (JP)

(72) Inventor: Tetsuya KAGAMI, Yamanashi (JP)

(21) Appl. No.: 16/613,372

(22) PCT Filed: Mar. 1, 2018
(86) PCT No.: PCT/JP2018/007805

§ 371 Date: Nov. 13, 2019

(30) Foreign Application Priority Data
May 15, 2017 (JP) 2017-096432

(51) Int. Cl. G01R 31/319; G01R 31/28; G01R 31/317

(52) U.S. Cl. CPC G01R 31/31919; G01R 31/31706; G01R 31/2851

(57) ABSTRACT

The present invention has a first step for inputting an inspection signal having a predetermined pattern simultaneously to a plurality of devices connected in parallel to a tester and starting inspection having a predetermined pattern, a second step for determining whether a non-passing device is included in the predetermined pattern, a third step for sequentially executing a predetermined pattern and determining passing/non-passing (PASS/FAIL) status for each of the plurality of devices when it is determined in the second step that a non-passing device is included, and a fourth step for excluding a device determined as non-passing in the third step, subsequent inspection being performed for the devices other than the excluded device.

### TECHNICAL FIELD

The present invention relates to a device inspection method for inspecting electrical characteristics of a device.

### BACKGROUND

Electrical characteristics of devices such as integrated circuits, semiconductor memories and the like formed on a semiconductor wafer (hereinafter, simply referred to as “wafer”) are inspected by an inspection apparatus having a probe card. The probe card includes a plurality of probes (contactors) to be in contact with electrode pads of the devices on the wafer. Electronic circuits on the wafer are inspected by transmitting electrical signals from a tester to the probes in a state where the probes are in contact with the electrode pads on the wafer.

Recently, as a wafer is scaled up, the number of devices formed on a single wafer increases dramatically. Therefore, a method for sequentially inspecting a plurality of inspection target devices (hereinafter, also referred to as “DUTs”) using one tester connected thereto is disadvantageous in that a long period of time is required to complete the inspection for all the DUTs.

Therefore, Patent Document 1 suggests a technique for determining whether or not one or more DUTs are FAIL based on a composite value of response signals transmitted from the DUTs after an inspection signal is inputted from a tester to a plurality of DUTs connected in parallel to the tester.

### PRIOR ART

Patent Document 1: Japanese Patent Application Publication No. 2016-35957

In the technique of Patent Document 1, it is possible to detect the presence of one or more FAIL DUTs by inspecting the DUTs using the tester. However, it is not possible to recognize which of the DUTs are FAIL because only PASS/FAIL of the DUTs is determined.

Therefore, in the case of performing predetermined inspection having a plurality of inspection patterns using the above technique, it is required to execute the inspection patterns even on the FAIL DUTs until the inspection is completed, which results in an increase in a total inspection time.

Therefore, an object of the present invention is to provide a device inspection method capable of performing predetermined inspection having a plurality of patterns on multiple devices within a short period of time.

### SUMMARY

In accordance with a first aspect of the present invention, there is provided a device inspection method for performing inspection having multiple patterns to inspect electrical characteristics of devices formed on a substrate using a tester, the method comprising: a first step of inputting an inspection signal having a predetermined pattern simultaneously to the devices formed on the substrate connected in parallel to the tester to start inspection having the predetermined pattern; a second step of determining whether or not a FAIL device is included in response to the predetermined pattern; a third step of sequentially inspecting the devices using the predetermined pattern and performing PASS/FAIL determination for each of the devices when it is determined in the second step that the FAIL device is included; a fourth step of excluding the device determined as FAIL in the third step, wherein subsequent inspection is performed on devices among the devices other than the excluded device.

Further, in the second step, whether or not the FAIL devices are included may be determined depending on whether or not a composite value of response signals transmitted from the devices after the inspection signal is inputted to the devices reaches a predetermined threshold value. Further, in the second step, it may be determined that the FAIL devices are included when the response signals do not reach a threshold value after a predetermined period of time has elapsed from the transmission of the inspection signal or when the response signals do not reach the threshold value after the inspection signal is transmitted at predetermined intervals a predetermined number of times.

Further, in the third step, PASS/FAIL of a predetermined device of the devices may be determined depending on whether or not a response signal transmitted from the predetermined device after the inspection signal is inputted to the predetermined device reaches the predetermined threshold value. Further, in the third step, it may be determined that the predetermined device of the devices is FAIL when the response signal does not reach the threshold value after a predetermined period of time has elapsed from the transmission of the inspection signal to the predetermined device or when the response signal does not reach the threshold value after the inspection signal is transmitted at predetermined intervals a predetermined number of times.

Further, after the fourth step, inspection of a subsequent pattern may be performed on devices other than the excluded device, and the remaining part of the inspection of the predetermined pattern may be performed on devices other than the excluded device.

Further, the third step may be executed in a state where only one device is connected to the tester and other devices are not connected to the tester.

In accordance with a second aspect of the present invention, there is provided a device inspection method for performing inspection having multiple patterns to inspect electrical characteristics of devices formed on a substrate using a tester, the method comprising: a first step of inputting an inspection signal having a predetermined pattern simultaneously to the devices formed on the substrate connected in parallel to the tester to start inspection having the predetermined pattern; a second step of detecting the number of FAIL devices in response to the predetermined pattern; a third step of sequentially inspecting the devices using the predetermined pattern and performing PASS/FAIL determination for each of the devices when one or more FAIL devices are detected in the second step; a fourth step of excluding the FAIL devices determined as FAIL in the third step, wherein the third step is terminated when the number of FAIL devices reaches the number detected in the second step, and subsequent inspection is performed on devices among the devices other than the excluded devices.

Further, in the second step, a preset threshold value may be compared with a composite value of response signals transmitted from the devices after the inspection signal is inputted to the devices, and it is determined that one or more devices are FAIL when the composite value does not reach the threshold value, and the number of the FAIL devices is detected by setting a new threshold value different from the threshold value, inputting the inspection signal from the tester simultaneously to the devices using the new threshold value, and determining whether or not one or more devices are FAIL based on the composite value of the response signals obtained in response to the inspection signal.

### Effect of the Invention

In accordance with the aspects of the present invention, after the inspection having a predetermined pattern is performed, it is determined whether or not FAIL devices are included in response to the predetermined pattern. When it is determined that the FAIL devices are included, the devices are sequentially inspected using the predetermined pattern and PASS/FAIL determination on each device is performed. Since subsequent inspection is performed on the devices other than the FAIL devices, predetermined inspection having multiple patterns can be performed within a short period of time.

### BRIEF DESCRIPTION OF THE DRAWINGS

FIG. 1 is a cross-sectional view showing a schematic configuration of an example of an inspection apparatus used for performing an inspection method of the present invention.

FIG. 2 schematically shows an example of a signal input/output circuit in the inspection apparatus of FIG. 1.

FIG. 3 is a cross-sectional view showing a hardware configuration of a control unit in the inspection apparatus of FIG. 1.

FIG. 4 is a functional block diagram of the control unit in the inspection apparatus of FIG. 1.

FIG. 5 shows a relationship among an inspection signal, a response signal, and a threshold value.

FIG. 6 is a flowchart showing an inspection method according to a first embodiment of the present invention.

FIG. 7 is a block diagram showing individual DUT determination in step 3 of the first embodiment.

FIG. 8 is a flowchart showing an inspection method according to a second embodiment of the present invention.

FIGS. 9A to 9C show magnitudes of composite response signals obtained by the inspection method according to the second embodiment.

FIG. 10 explains threshold values for the composite response signals in the inspection method according to the second embodiment.

FIG. 11 is a flowchart for explaining step 12 of the inspection method according to the second embodiment.

FIG. 12 is a block diagram showing individual DUT determination in step 14 of the second embodiment.

### DETAILED DESCRIPTION

Hereinafter, embodiments will be described in detail with reference to the accompanying drawings.

<Inspection Apparatus>

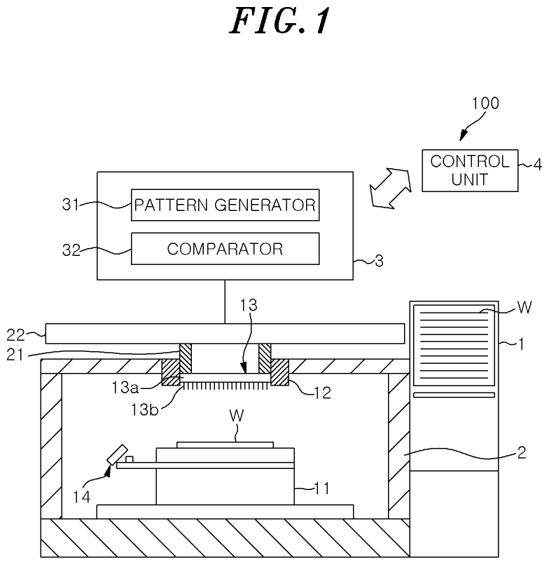

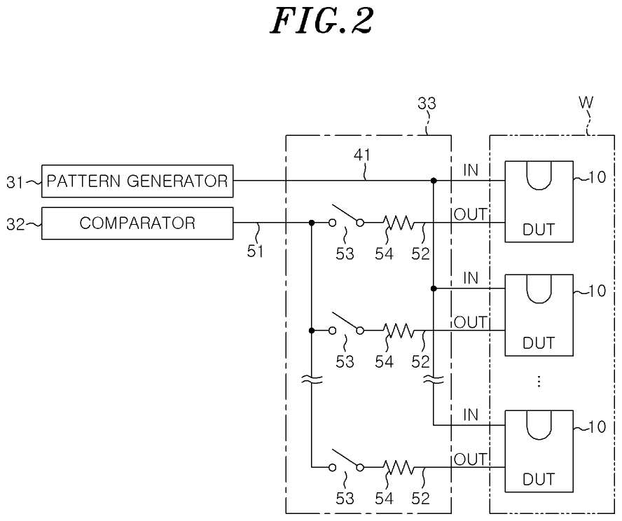

FIG. 1 is a cross-sectional view showing a schematic configuration of an example of an inspection apparatus used for performing an inspection method of the present invention. FIG. 2 schematically shows an example of a signal input/output circuit in the inspection apparatus of FIG. 1.

In FIG. 1, an inspection apparatus 100 includes: a loader chamber 1 forming a transfer region for transferring a wafer W; an inspection chamber 2 accommodating a wafer W on which a plurality of inspection target devices (DUTs) 10 (only shown in FIG. 2) is formed; a tester 3 that transmits electrical signals to the DUTs 10 and receives response signals from the DUTs 10 to inspect electrical characteristics of the DUTs 10 on the wafer W; and a control unit 4 for controlling the respective components of the inspection apparatus 100.

The inspection chamber 2 includes: a mounting table 11 having a driving unit (not shown) for moving a wafer W mounted thereon in X, Y, Z, and θ directions; a holder 12 disposed above the mounting table 11; a probe card 13 supported by the holder 12 and having a support substrate 13a and a plurality of probes (contactors) 13b; and an alignment mechanism 14 for performing alignment of the probes 13b and electrode pads (not shown) of the DUTs 10 formed on the wafer W. The probe card 13 is electrically connected to the tester 3 via a connection ring 21 having multiple connection terminals, an interposer (performance board) 22, and a test head (not shown). The tester 3 includes a pattern generator 31 and a comparator 32.

As shown in FIG. 2, the pattern generator 31, the comparator 32, and the DUTs 10 are electrically connected by a signal input/output circuit 33. The signal input/output circuit 33 shown in FIG. 2 is an example and is not limited thereto.

The pattern generator 31 generates an inspection signal for inspecting the DUTs 10. The pattern generator 31 and the DUTs 10 are connected by an input line 41 branched into multiple parts.

The comparator 32 compares a threshold value with response signals outputted from the DUTs 10 in response to the inspection signal transmitted from the pattern generator 31 or with a signal (composite response signal) obtained by combining the response signals from the DUTs 10. The comparator 32 is connected to a common output line 51 and individual output lines 52 from the DUTs 10. The response signals outputted from the DUTs 10 are transmitted to the comparator 32 through the individual output lines 52 and the common output line 51.

The signal input/output circuit 33 includes the input line 41, the common output line 51, the individual output lines 52, relay switch units 53, and resistance elements 54. The signal input/output circuit 33 may be mounted on any one of the tester 3, the support substrate 13a of the probe card 13, and the interposer (performance board) 22.

The input line 41 is branched to correspond to the DUTs 10, and connects the pattern generator 31 and the DUTs 10 in parallel. The inspection signal generated by the pattern generator 31 is transmitted to the DUTs 10 through the input line 41. The input line 41 may be provided with a relay switch unit for switching connection/disconnection between the pattern generator 31 and the DUTs 10.

In each of the individual output lines 52, the relay switch unit 53 and the resistance element 54 are disposed in series. The arrangement order of the relay switch unit 53 and the resistance element 54 is not fixed.

The relay switch unit 53 switches connection/disconnection between the comparator 32 and the DUTs 10. In the case of combining the response signals from the DUTs 10 into one, all the relay switch units 53 are connected (ON). In the case of individually transmitting the response signals from the DUTs 10 to the comparator 32, a relay switch unit 53 of one individual output line 52 is connected (ON), and relay switch units 53 of the other individual output lines 52 are disconnected (OFF). The connection/disconnection between the comparator 32 and the DUTs 10 is not necessarily switched by the relay switch unit 53, and may be switched by another switching device such as a transistor or the like.

The resistance element 54 selects a response signal. Further, the resistance element 54 has a resistance greater than internal resistances (output impedances) of the DUTs 10 to adjust an impedance in the common output line 51 connected to the individual output lines 52.

The tester 3 may include multiple sets of pattern generators 31 and comparators 32 to inspect a predetermined number of DUTs 10.

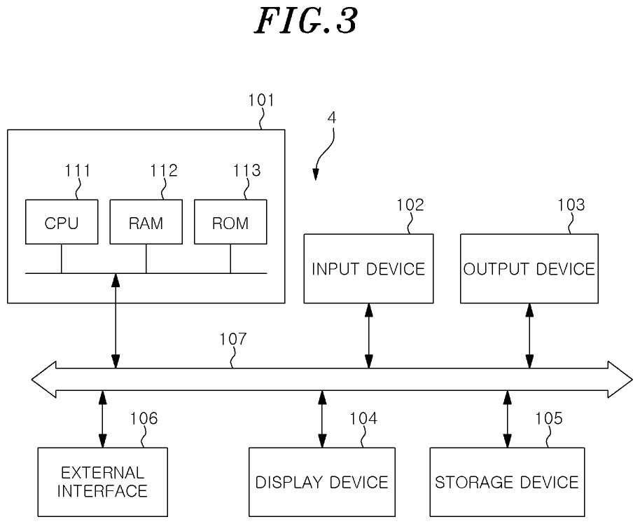

The control unit 4 controls the respective components of the inspection apparatus 100, such as the pattern generator 31 and the comparator 32 of the tester 3, the driving unit of the mounting table 11, the alignment mechanism 14, the relay switch units 53, and the like. The control unit 4 is typically a computer. FIG. 3 shows an example of a hardware configuration of the control unit 4 shown in FIG. 1. The control unit 4 includes a main controller 101, an input device 102 such as a keyboard, a mouse or the like, an output device 103 such as a printer or the like, a display device 104, a storage device 105, an external interface 106, and a bus 107 that connects these devices. The main controller 101 includes a central processing unit (CPU) 111, a random access memory (RAM) 112, and a read only memory (ROM) 113. The storage device 105 stores information in a computer-readable storage medium and reads out the information therefrom. The storage medium may include, e.g., a semiconductor memory such as a hard disk, an optical disk, or a flash memory. The storage medium stores a recipe or the like for performing the inspection method of the present embodiment.

In the control unit 4, the CPU 111 executes a program stored in the storage medium of the ROM 113 or the storage device 105 using the RAM 112 as a work area. Accordingly, the inspection apparatus 100 inspects the DUTs 10 formed on the wafer W.

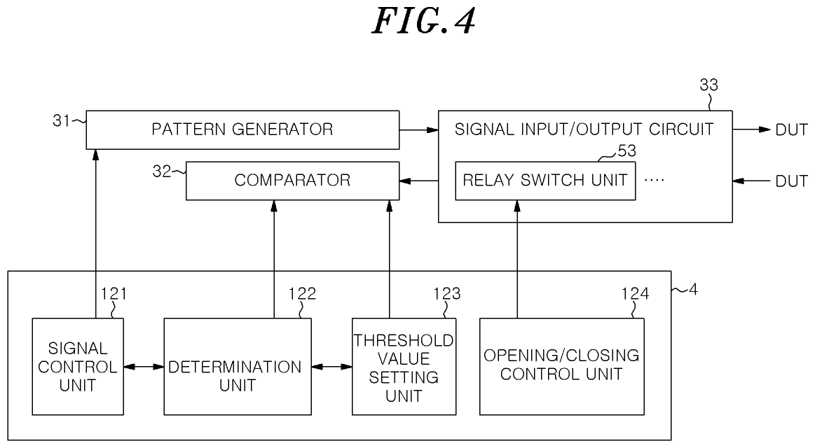

FIG. 4 is a functional block diagram of the control unit 4 and shows the relationship among the pattern generator 31, the comparator 32, and the relay switch unit 53. As shown in FIG. 4, the control unit 4 includes a signal control unit 121, a determination unit 122, a threshold value setting unit 123, and an opening/closing control unit 124. These devices operate when the CPU 111 executes software (program) stored in the ROM 113 or the storage device 105 using the RAM 112 as a work area. For example, the probe card 13 or the interposer (performance board) 22 may have the same functions as those of the signal control unit 121, the determination unit 122, and the threshold value setting unit 123 using a field programmable gate array (FPGA) or the like. Although the control unit 4 has other functions, detailed description thereof will be omitted.

The signal control unit 121 controls the pattern generator 31 to generate an inspection signal. Specifically, the signal control unit 121 transmits to the pattern generator 31 a control signal including types of clock signals and data signals generated by the pattern generator 31 and instructions such as start/stop of generation of these signals.

The determination unit 122 acquires comparison information between the threshold value and the composite response signal from the comparator 32, and determines whether or not there is a FAIL DUT among the DUTs 10 based on the comparison information. Further, the determination unit 122 acquires comparison information between the threshold value and the response signals from the comparator 32 and determines PASS/FAIL of the DUTs 10.

The threshold value setting unit 123 sets a threshold value for comparison in the comparator 32.

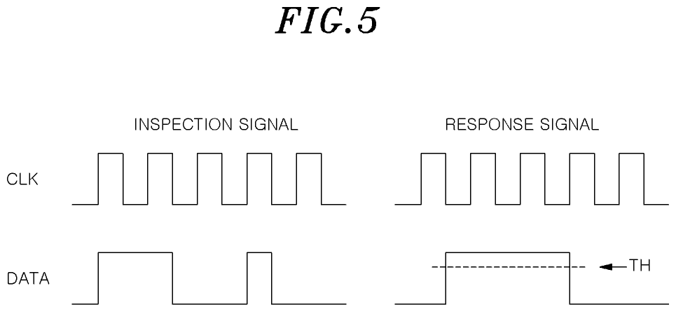

FIG. 5 explains an inspection signal, a response signal, and a threshold value. The pattern generator 31 generates a clock signal (CLK) and a data signal (DATA). These signals are inputted as the inspection signal to the DUTs 10. As a consequence, response signals are outputted from the DUTs 10. The comparator 32 compares the threshold value set by the threshold value setting unit 123 with the composite response signal or with the response signals from the DUTs based on the level of the composite response signal or the levels of the response signals.

If the composite response signal does not reach the threshold value, it is determined that there is a FAIL DUT. If the response signals from the DUTs do not reach the threshold value, the corresponding DUTs are determined as FAIL. For example, on the assumption that a threshold value TH for comparison in the comparator 32 is 3V, the determination result is FAIL when the response signal is lower than 3V.

At this time, since the response time varies depending on the DUTs, an elapsed time from the transmission of the inspection signal from the pattern generator 31 is monitored. A flag is on if the response signal does not reach the threshold value after a predetermined time of time has elapsed. Alternatively, a flag is on if the response signal does not reach the threshold value after the inspection signal is transmitted from the pattern generator 31 at predetermined intervals a predetermined number of times. The determination result of the determination unit 122 is FAIL when it is recognized that the flag is ON. The monitoring at this time may be performed by either software or hardware.

In a mode for determining whether or not there is a FAIL DUT 10 among the DUTs 10 based on the composite response signal, the opening/closing control unit 124 transmits an instruction of connecting all of the relay switch units 53. In a mode for determining PASS/FAIL of the DUTs 10, the opening/closing control unit 124 transmits to the relay switch units 53 instructions of connecting relay switch units 53 corresponding to DUTs 10 to be subjected to PASS/FAIL determination.

### Inspection Method of First Embodiment

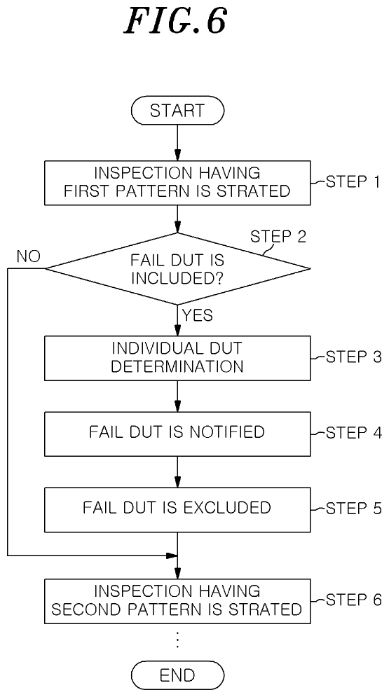

Next, an inspection method according to the first embodiment of the present invention which is performed by the inspection apparatus 100 will be described with reference to FIG. 6. FIG. 6 is a flowchart showing the inspection method according to the first embodiment of the present invention.

In the present embodiment, one inspection has multiple patterns, and the inspections of the multiple patterns are consecutively performed.

First, an inspection signal having a first pattern is inputted to each of the DUTs 10 in a state where the relay switch units 53 are closed in response to an instruction from the opening/closing control unit 124 to start inspection having the first pattern (step 1). In this step, the inspection signal having the same pattern is simultaneously inputted to all the DUTs 10.

Next, it is determined whether or not a FAIL DUT is included in the first pattern (step 2). At this time, the comparator 32 compares the threshold value set by the threshold value setting unit 123 with the composite response signal as described above. For example, the elapsed time from the transmission of the inspection signal from the pattern generator 31 is monitored. Alternatively, the inspection signal is transmitted from the pattern generator 31 at predetermined intervals, and the number of transmission is monitored. A flag is on if the response signals do not reach the threshold value after a predetermined period of time has elapsed, or if the composite response signal does not reach the threshold value after the inspection signal is transmitted a predetermined number of times. The determination unit 122 determines that a FAIL DUT is included when it is recognized that the flag is on.

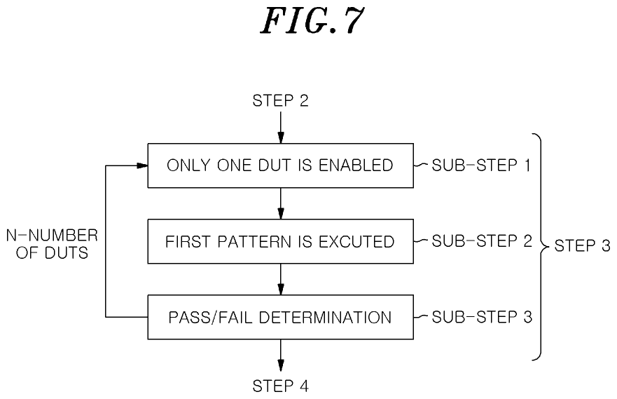

When it is determined in step 2 that a FAIL DUT is included, the processing proceeds to individual DUT determination (step 3). In step 3 of the individual DUT determination, only one relay control unit 124 is switched ON (the other relay switch units 53 are switched off) by the opening/closing control unit 124 to enable only one DUT (sub-step 1); the first pattern is sequentially executed (sub-step 2); and PASS/FAIL determination is performed on all the (n-number of) DUTs 10 (sub-step 3), as shown in FIG. 7. In this determination, the comparator 32 compares the threshold value set by the threshold value setting unit 123 with the response signals from the DUT 10 as described above. For example, the elapsed time from the transmission of the inspection signal from the pattern generator 31 is monitored. Alternatively, the number of the transmission of the inspection signal from the pattern generator 31 at predetermined intervals is monitored. A flag is on if the response signals do not reach the threshold value after a predetermined period of time has elapsed, or if the composite response signal does not reach the threshold value after the inspection signal is transmitted a predetermined number of times. The determination unit 122 determines that the DUT is FAIL when it is recognized that the flag is on.

Next, the FAIL DUT is notified (step 4). Then, the FAIL DUT is separated and excluded from the inspection of the subsequent pattern (step 5). At this time, the FAIL DUT may be separated in a state where the relay switch unit 53 of the DUT is switched OFF, or the DUT may be disabled on software.

Next, an inspection signal having a second pattern is inputted to each of the DUTs 10 in a state where all the relay switch units 53 are closed in response to an instruction from the opening/closing control unit 124 to start inspection having the second pattern (step 6). At this time, if a FAIL DUT is disconnected, the remaining DUTs are inspected.

Then, the inspection is performed in the same manner as in steps 2 to 5. The multiple inspection patterns are sequentially executed.

When the composite response signal reaches the threshold value and all the DUTs are determined as PASS in step 2, the inspection having the second pattern inspection is performed on all the DUTs without performing steps 3 to 5.

Conventionally, in the case of performing inspection having multiple inspection patterns, even if a FAIL DUT is included, all the inspection patterns are executed and, then, the FAIL DUT is specified. Therefore, even when a FAIL DUT is included in one inspection pattern, it is required to execute a pattern for determining PASS/FAIL of all the DUTs including the FAIL DUT in the inspection of the subsequent pattern. Accordingly, when the pattern is executed, it is required to wait until a predetermined period of time elapses or until a predetermined number of times elapses, which results in an increase in a total inspection time.

On the other hand, in the present embodiment, when it is determined that a FAIL DUT is included in one inspection pattern, the FAIL DUT is specified by performing individual DUT inspection on the DUTs. When inspection of a subsequent pattern is performed, the FAIL DUT is excluded. Thus, inspection of a subsequent item or a subsequent pattern can be performed within a short period of time, and the total inspection time can be shortened.

### Inspection Method of the Second Embodiment

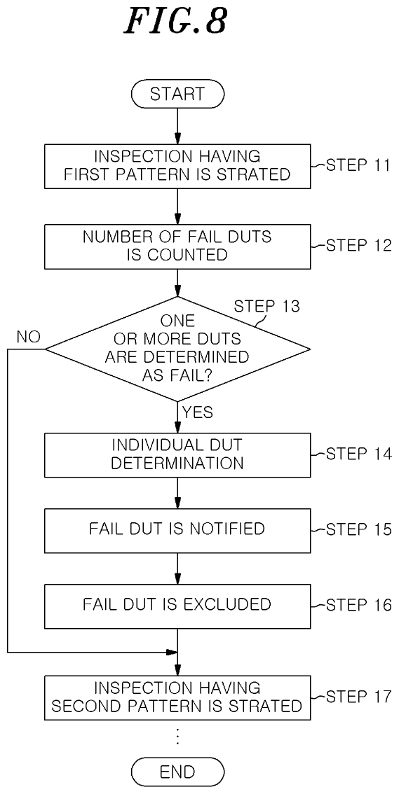

Next, an inspection method according to the second embodiment will be described. FIG. 8 is a flowchart showing the inspection method of the second embodiment.

In the present embodiment as well, one inspection has multiple patterns, and the inspections of the multiple patterns are consecutively performed.

First, inspection having a first pattern is performed on the DUTs 10 in a state where all the relay switch units 53 are closed in response to an instruction from the opening/closing control unit 124 (step 11).

Next, the number of FAIL DUTs in the first pattern is counted (step 12).

In the present embodiment, the threshold value setting unit 123 can set a plurality of threshold values in multiple stages, and the threshold values can be dynamically changed. For example, when the determination unit 122 (or the comparator 32) determines that one or more DUTs 10 are FAIL based on the comparison information between the first threshold value and the composite response signal, the threshold value setting unit 123 can set a second threshold value as a new threshold value different from the first threshold value. Since the threshold value setting unit 123 can set a plurality of threshold values, the number of FAIL DUTs can be detected as follows.

A method for setting a threshold value in the threshold value setting unit 123 will be described with reference to FIGS. 5, 9 and 10. Referring to FIG. 5, in order to determine PASS/FAIL of the DUTs 10, the clock signal (CLK) and the data signal (DATA) generated by the pattern generator 31 are inputted as the inspection signal to the DUTs 10. As a consequence, the response signals are outputted from the DUTs 10, and the comparator 32 determines PASS/FAIL of the DUTs 10 based on the levels of the response signals. For example, on the assumption that the threshold value TH for the comparison in the comparator 32 is 3V, the determination result is PASS when the response signal is higher than or equal to 3V and the determination result is FAIL when the response signal is lower than 3V. The individual response signals from the DUTs 10 may include a PASS signal that satisfies the threshold value TH and a FAIL signal that does not satisfy the threshold value TH. Therefore, the composite response signal may be obtained by combining only the PASS signals, or combining only the FAIL signal, or combining the PASS signal and the FAIL signal.

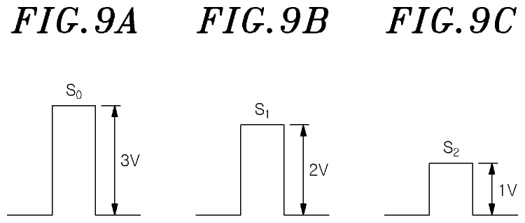

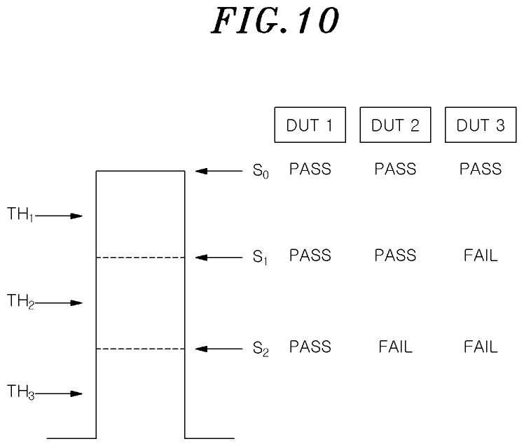

FIGS. 9A to 9C show magnitudes (e.g., voltage values) of the composite response signals obtained in step 12. FIG. 10 shows an example of setting threshold values for the composite response signals in step 12. In FIGS. 9 and 10, three DUTs 10 are illustrated for convenience of description. The signals inputted from the pattern generator 31 to the DUTs 10 have the same level and the same pattern. On the other hand, the individual response signals from the DUTs 10 may include a PASS signal and a FAIL signal as described above. The composite response signal obtained by combining only PASS signals has a value different from that of the composite response signal obtained by combining a PASS signal and a FAIL signal.

For example, when the response signals from the DUTs 10 have two output levels of High (PASS) (3 V) and Low (FAIL) (0 V), if output levels S_{D} of individual response signals of three DUTs 10 are all High, an output level S₀ of the composite response signal becomes 3 V as shown in FIG. 9A.

When the output levels of the individual response signals of two DUTs 10 among the three DUTs 10 are High and the output level of the individual response signal of one DUT 10 is Low, an output level S₁ of the composite response signal becomes 2 V (=3 V×(3−1)/3) as shown in FIG. 9B.

When the output level of the individual response signal of one DUT 10 among the three DUTs 10 is High and the output levels of the individual response signals of the two DUTs 10 is Low, an output level S₂ of the composite response signal becomes 1 V (=3 V×(3−2)/3) as shown in FIG. 9C. The DUTs 10 have the same output impedance of High (3 V) and Low (0 V).

In other words, when all the n-number of DUTs 10 output PASS signals having the same output level S_{D}[V], the output level S₀ of the composite response signal is S₀[V]=S_{D}[V]×n/n. When one of the n-number of DUTs 10 outputs a FAIL signal and the other DUTs 10 output PASS signals, the output level S₁ of the composite response signal is S₁[V]=S_{D}[V]×(n−1)/n. When two of the n-number of DUTs 10 output FAIL signals and the other DUTs 10 output PASS signals, the output level S₂ of the composite response signal is S₂[V]=S_{D}[V]×(n−2)/n.

In step 12, the comparator 32 sequentially compares the output level of the composite response signal with threshold values TH₁, TH₂, TH₃, . . . . The determination unit 122 determines that “all the DUTs 10 are PASS” when the output level of the composite response signal satisfies the threshold value TH and determines that “one or more DUTs 10 are FAIL” when the output level of the composite response signal does not satisfy the threshold value TH.

As shown in FIG. 10, a threshold value TH₁ used in first determination may be set between the output level S₀ of the composite response signal in the case where all three DUTs 10 are PASS and the output level S₁ of the composite response signal in the case where one DUT 10 is FAIL. Accordingly, when the output level of the composite response signal is higher than or equal to the threshold value TH₁, it is determined that all the DUTs 10 are PASS. When the output level of the composite response signal is lower than the threshold value TH₁, it is determined that one or more DUTs 10 are FAIL.

A threshold value TH₂ used in the second determination may be set between the output level S₁ of the composite response signal in the case where one DUT 10 is FAIL and the output level S₂ of the composite response signal in the case where two DUTs 10 are FAIL. Accordingly, when the output level of the composite response signal is higher than or equal to the threshold value TH₂, it is determined that two DUTs 10 are PASS and one DUT 10 is FAIL considering together with the first determination result. If the output level of the composite response signal is lower than the threshold value TH₂, it is determined that two or more DUTs 10 are FAIL.

A threshold value TH₃ used in third determination may be set to be lower than the output level Sₛ of the composite response signal in the case where two DUTs 10 are FAIL. Accordingly, when the output level of the composite response signal is higher than or equal to the threshold value TH₃, it is determined that one DUT 10 is PASS and two DUTs 10 are FAIL considering together with the first determination result and the second determination result. If the output level of the composite response signal is lower than the threshold value TH₂, it is determined that three DUTs 10 are FAIL.

In the case of performing the determination while decreasing the threshold level step by step, if the threshold value set in an N-th determination (N being a positive integer of 1 or more) is set to TH_{N} and a threshold value set for an N+1th determination is set to TH_{N+1} for n-number (n being a positive integer of 2 or more) of DUTs 10, the relationship TH_{N}>TH_{N+1} is satisfied. The threshold value TH_{N} set in the N-th determination for the output level S₀ of the composite response signal in the case where all the n-number of DUTs 10 is PASS preferably satisfies the relationship expressed by the following Eq. (1):

S₀×(n−(N−1))/n≥TH_{N}>S₀×(n−N)/n Eq. (1).

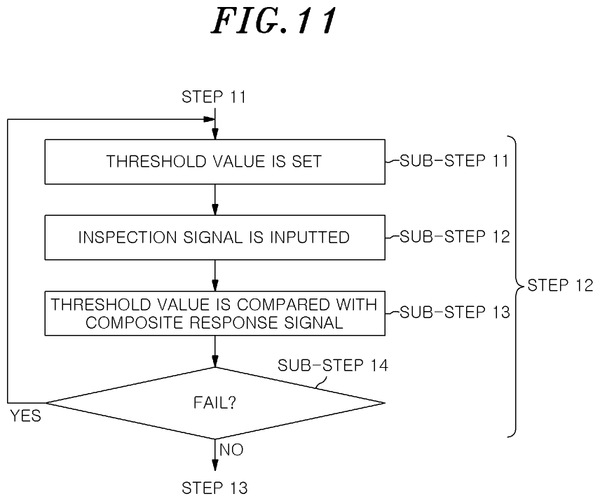

A specific procedure of step 12 will be described with reference to FIG. 11. FIG. 11 is a flowchart showing an example of the procedure of step 12. Step 12 includes the following sub-steps 11 to 14.

In sub-step 11, the threshold value TH₁ used in the first determination is set. The threshold value TH₁ is set by the threshold value setting unit 123. In the above Eq. (1), the threshold value TH₁ set in the first determination for the output level S₀ of the composite response signal in the case where all the n-number of DUTs 10 are PASS preferably satisfies the following relationship:

S₀×n/n≥TH₁>S₀×(n−1)/n.

In sub-step 12, the clock signal and the data signal are generated by the pattern generator 31 based on the instruction from the signal control unit 121, and the same inspection signal is simultaneously inputted to all the n-number of DUTs 10.

In sub-step 13, the comparator 32 compares the threshold value TH₁ with the composite value (composite response signal) of the response signals outputted from the DUTs 10 in response to the inspection signal. In this case, all the relay switch units 53 are maintained in a connection state (ON).

Next, in sub-step 14, the determination unit 122 acquires the comparison information between the threshold value TH₁ and the composite response signal from the comparator 32, and determines whether or not one or more DUTs 10 among the n-number of DUTs 10 are FAIL, i.e., whether or not all the DUTs 10 are PASS, based on the comparison information.

If it is determined in sub-step 14 that “one or more DUTs 10 among THE n-number of DUTs 10 are FAIL” (YES), the processing returns to sub-step 11. In other words, in sub-step 11, the threshold value setting unit 123 sets the threshold value TH₂ used in the second determination as a new threshold value. In the above Eq. (1), the threshold value TH₂ set in the second determination for the output level S₀ of the composite response signal in the case where all the n-number of DUTs 10 are PASS preferably satisfies the following relationship:

S₀×(n−1)/n≥TH₂>S₀×(n−2)/n.

When a new threshold value (e.g., the threshold value TH₂ used in the second determination) is set in sub-step 11, sub-steps 12 to 14 are executed and the second determination is performed. Sub-steps 11 to 14 are repeatedly executed in a loop until it is determined in sub-step 14 that “one or more DUTs 10 among the n-number of DUTs 10 are not FAIL” (NO). When the number of repetition reaches a preset upper limit, the determination unit 122 transmits stop signals to the signal control unit 121 and the threshold value setting unit 123.

If it is determined in sub-step 14 that “one or more DUTs among the n-number of DUTs 10 are not FAIL” (NO), step 12 is terminated.

In step 12, the number of FAIL DUTs 10 among the n-number of DUTs 10 can be determined by changing the threshold value TH in response to the composite response signals S₀, S₁, S₂, . . . , S_{N} (N being a positive integer of 1 or more) in the case where the number of FAIL DUTs 10 is increased by one from zero.

In other words, the number of FAIL DUTs 10 among the n-number of DUTs 10 can be automatically determined by repeatedly executing sub-steps 11 to 14 while changing the threshold value TH.

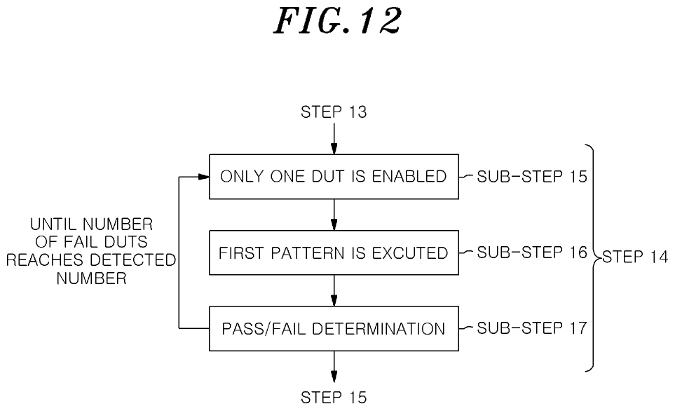

After step 12 is executed, it is determined whether or not one or more DUTs 10 were determined as FAIL in step 12 (step 13). When one or more DUTs 10 are FAIL, the individual DUT determination is performed as in step 3 of the first embodiment (step 14). Step 14 is executed in the same manner as step 3 of the first embodiment. Since, however, the number of FAIL DUTs was detected in step 12, step 14 can be terminated when the number of FAIL DUTs reaches the detected number. In other words, in step 14, as shown in FIG. 12, one of the relay switch units 53 is switched on (the other relay switch units 53 are switched off) by the opening/closing control unit 124 to enable only one DUT (sub-step 15); the first pattern is sequentially executed (sub-step 16); and the PASS/FAIL determination is performed until the number of FAIL DUTs reaches the detected number (sub-step 17).

Thereafter, the FAIL DUT is notified in the same manner as in step 4 of the first embodiment (step 15). Then, as in step 5, the FAIL DUT is separated and excluded from the inspection of the subsequent pattern (step 16).

Next, the inspection of the subsequent pattern is performed on the DUTs 10 in a state where all the relay switch units 53 are closed in response to an instruction from the opening/closing control unit 124 (step 17). At this time, when the FAIL DUT is disconnected, the inspection is performed on the remaining DUTs 10.

Next, the inspection is performed in the same manner as in steps 12 to 16. Then, the inspection patterns are sequentially executed.

If it is determined in step 13 that the number of FAIL DUTs is zero, the inspection of the subsequent pattern is performed on all DUTs 10 without performing steps 14-16.

In the present embodiment, when it is determined that a FAIL DUT exists in one inspection pattern, the individual DUT inspection is performed on all the DUTs. The FAIL DUT is notified and excluded from the inspection of the subsequent pattern. Therefore, it is possible to obtain the same effect as that of the first embodiment in which the inspection of the subsequent item or the subsequent pattern can be performed within a short period of time. In addition, since step 14 is terminated when the number of the FAIL DUTs 10 reaches the number detected in step 12, the total inspection time can be further shortened compared to that in the first embodiment.

### OTHER APPLICATIONS

While two embodiments of the present invention have been described above, the present invention is not limited thereto, and various modifications can be made. For example, it is possible to apply the inspection method of the present invention regardless of types of devices as long as devices that output READY signal/BUSY signal are inspected collectively.

The first embodiment has described the example in which the inspection of the subsequent pattern is performed on devices other than the excluded device after step 5. However, the remaining part of the inspection of the predetermined pattern that is being executed may be performed on devices other than the excluded device after step 5.

### DESCRIPTION OF REFERENCE NUMERALS

3: tester
4: control unit
10: device under test (DUT)
31: pattern generator
32: comparator
33: signal input/output circuit
41: input line
51: common output line
52: individual output line
53: relay switch unit
54: resistance element
100: inspection apparatus
121: signal control unit
122: determination unit
123: threshold value setting unit
124: opening/closing control unit
W: semiconductor wafer

1. A device inspection method for performing inspection having multiple patterns to inspect electrical characteristics of devices formed on a substrate using a tester, the method comprising:
a first step of inputting an inspection signal having a predetermined pattern simultaneously to the devices formed on the substrate connected in parallel to the tester to start inspection having the predetermined pattern;
a second step of determining whether or not a FAIL device is included after performing the inspection having the predetermined pattern;
a third step of sequentially inspecting the devices using the predetermined pattern and performing PASS/FAIL determination for each of the devices when it is determined in the second step that the FAIL device is included;
a fourth step of excluding the device determined as FAIL in the third step,
wherein subsequent inspection is performed on devices among the devices other than the excluded device.

2. The device inspection method of claim 1, wherein in the second step, whether or not the FAIL devices are included is determined depending on whether or not a composite value of response signals transmitted from the devices after the inspection signal is inputted to the devices reaches a predetermined threshold value.

3. The device inspection method of claim 2, wherein in the second step, it is determined that the FAIL devices are included when the response signals do not reach a threshold value after a predetermined period of time has elapsed from the transmission of the inspection signal or when the response signals do not reach the threshold value after the inspection signal is transmitted at predetermined intervals a predetermined number of times.

4. The device inspection method of claim 1, wherein in the third step, PASS/FAIL of a predetermined device of the devices is determined depending on whether or not a response signal transmitted from the predetermined device after the inspection signal is inputted to the predetermined device reaches the predetermined threshold value.

5. The device inspection method of claim 4, wherein in the third step, it is determined that the predetermined device of the devices is FAIL when the response signal does not reach the threshold value after a predetermined period of time has elapsed from the transmission of the inspection signal to the predetermined device or when the response signal does not reach the threshold value after the inspection signal is transmitted at predetermined intervals a predetermined number of times.

6. The device inspection method of claim 1, wherein after the fourth step, inspection having a subsequent pattern is performed on devices other than the excluded device.

7. The device inspection method of claim 1, wherein after the fourth step, a remaining part of the inspection of the predetermined pattern is performed on devices other than the excluded device.

8. The device inspection method of claim 1, wherein the third step is executed in a state where only one device is connected to the tester and other devices are not connected to the tester.

9. A device inspection method for performing inspection having multiple patterns to inspect electrical characteristics of devices formed on a substrate using a tester, the method comprising:
a first step of inputting an inspection signal having a predetermined pattern simultaneously to the devices formed on the substrate connected in parallel to the tester to start inspection having the predetermined pattern;
a second step of detecting a number of FAIL devices in after performing the inspection having the predetermined pattern;
a third step of sequentially inspecting the devices using the predetermined pattern and performing PASS/FAIL determination for each of the devices when one or more FAIL devices are detected in the second step;
a fourth step of excluding the FAIL devices determined as FAIL in the third step,
wherein the third step is terminated when the number of FAIL devices reaches the number detected in the second step, and
subsequent inspection is performed on devices among the devices other than the excluded FAIL devices.

10. The device inspection method of claim 9, wherein in the second step, a preset threshold value is compared with a composite value of response signals transmitted from the devices after the inspection signal is inputted to the devices, and it is determined that one or more devices are FAIL when the composite value does not reach the threshold value, and
the number of the FAIL devices is detected by setting a new threshold value different from the threshold value, inputting the inspection signal from the tester simultaneously to the devices using the new threshold value, and determining whether or not one or more devices are FAIL based on the composite value of the response signals obtained in response to the inspection signal.

11. The device inspection method of claim 2, wherein in the third step, PASS/FAIL of a predetermined device of the devices is determined depending on whether or not a response signal transmitted from the predetermined device after the inspection signal is inputted to the predetermined device reaches the predetermined threshold value.

12. The device inspection method of claim 3, wherein in the third step, PASS/FAIL of a predetermined device of the devices is determined depending on whether or not a response signal transmitted from the predetermined device after the inspection signal is inputted to the predetermined device reaches the predetermined threshold value.

13. The device inspection method of claim 2, wherein after the fourth step, inspection having a subsequent pattern is performed on devices other than the excluded device.

14. The device inspection method of claim 3, wherein after the fourth step, inspection having a subsequent pattern is performed on devices other than the excluded device.

15. The device inspection method of claim 2, wherein after the fourth step, a remaining part of the inspection of the predetermined pattern is performed on devices other than the excluded device.

16. The device inspection method of claim 3, wherein after the fourth step, a remaining part of the inspection of the predetermined pattern is performed on devices other than the excluded device.

17. The device inspection method of claim 2, wherein the third step is executed in a state where only one device is connected to the tester and other devices are not connected to the tester.

18. The device inspection method of claim 2, wherein the third step is executed in a state where only one device is connected to the tester and other devices are not connected to the tester.
